(19) United States
(12) Patent Application Publication
(10) Pub. No.: US 2020/0200986 A1
(43) Pub. Date: Jun. 25, 2020

(54) PLUGGABLE OPTICAL MODULE AND HOST BOARD

(71) Applicant: Sumitomo Electric Industries, Ltd., Osaka-shi, Osaka (JP)

(72) Inventors: Tomoyuki FUNADA, Osaka-shi, Osaka (JP); Daisuke UMEDA, Osaka-shi, Osaka (JP); Daisuke KAWASE, Osaka-shi, Osaka (JP); Naruto TANAKA, Osaka-shi, Osaka (JP)

(73) Assignee: Sumitomo Electric Industries, Ltd., Osaka-shi, Osaka (JP)

(21) Appl. No.: 16/644,263

(22) PCT Filed: Jul. 4, 2018
(86) PCT No.: PCT/JP2018/025357

§ 371 Date: Mar. 4, 2020

(30) Foreign Application Priority Data
Sep. 8, 2017 (JP) 2017-172790

(51) Int. Cl. G02B 6/42; H05K 1/11; H01R 12/72

(52) U.S. Cl. CPC G02B 6/4278; G02B 6/4261; G02B 6/4246; H04B 10/27; H01R 12/72; H05K 2201/09409; H05K 1/117

(57) ABSTRACT

A pluggable optical module includes: a circuit board insertable to and removable from a connector of a host board; a plurality of first electrodes arranged in a first direction, which crosses an insert direction of the pluggable optical module, on a first surface of the circuit board; and a plurality of second electrodes arranged in the first direction on the first surface of the circuit board, the second electrodes being arranged on a host board side associated with the host board, with respect to the plurality of first electrodes. The first and second electrodes are arranged in accordance with a layout rule for tolerating electrical impact occurring when at least one of a plurality of terminals of the connector configured to be brought into contact with respective first electrodes of the plurality of first electrodes contacts any electrode of the plurality of second electrodes.

### TECHNICAL FIELD

The present invention relates to a pluggable optical module and a host board. The present application claims priority to Japanese Patent Application No. 2017-172790 filed on Sep. 8, 2017, the disclosure of which is herein incorporated by reference in its entirety.

### BACKGROUND ART

With the increasing capacity of optical communications, a higher density and a smaller size of optical modules such as optical transceiver are required. For example, in 100 GbE (Gigabit Ethernet®) applications, QSFP (Quad Small Form-Factor Pluggable) 28 is used as a form factor for optical transceivers. As a 400 GbE interface, a QSFP-DD (Quad Small Form-factor Pluggable-Double Density) module has been proposed, and the specification for the QSFP-DD module is prepared (see NPL 1). The QSFP-DD module has two rows of electrodes, and is longer than QSFP28/QSFP+ by the length of the electrodes in the second row. Meanwhile, a QSFP-DD cage (a socket on the host board side) provides backwards compatibility to all QSFP modules.

### CITATION LIST

### Non Patent Literature

NPL 1: “QSFP-DD Specification for QSFP Double Density 8× Pluggable Transceiver Rev 2.0”, [online], Mar. 13, 2017, QSFP-DD MSA, [searched Aug. 8, 2017], Internet <URL:http://www.qsfp-dd.com/wp-content/uploads/2017/03/QSFP-DDrev2-0-Final.pdf

### SUMMARY OF INVENTION

A pluggable optical module according to an aspect of the present invention includes: a circuit board insertable to and removable from a connector of a host board; a plurality of first electrodes arranged in a first direction on a first surface of the circuit board, the first direction crossing an insert direction in which the pluggable optical module is to be inserted; and a plurality of second electrodes arranged in the first direction on the first surface of the circuit board, the second electrodes being arranged on a host board side associated with the host board, with respect to the plurality of first electrodes. The plurality of first electrodes and the plurality of second electrodes are arranged in accordance with a layout rule for tolerating electrical impact occurring when at least one of a plurality of terminals of the connector that are configured to be brought into contact with respective first electrodes of the plurality of first electrodes contacts any electrode of the plurality of second electrodes.

A host board according to an aspect of the present invention includes a connector attachable to and detachable from a host interface of a pluggable optical module. The host interface of the pluggable optical module has a surface on which a plurality of first electrodes are arranged in a row and a plurality of second electrodes are arranged in a row. The plurality of second electrodes are arranged on a host board side associated with the host board, with respect to the plurality of first electrodes. The host board further includes a circuit board on which the connector is mounted. The connector includes: a plurality of first terminals to be brought into contact with respective first electrodes of the plurality of first electrodes of the host interface; and a plurality of second terminals to be brought into contact with respective second electrodes of the plurality of second electrodes of the host interface. The plurality of first terminals and the plurality of second terminals are arranged on the connector in accordance with a pin assignment for tolerating electrical impact that may occur when at least one of the plurality of first terminals of the connector contacts any electrode of the plurality of second electrodes of the host interface.

### BRIEF DESCRIPTION OF DRAWINGS

FIG. 1 is a schematic diagram of a PON system according to an embodiment.

FIG. 2 is a block diagram schematically showing an application including a host board and an optical transceiver.

FIG. 3 shows a stage where a 10 Gbps system and a 25 Gbps system coexist in one scenario in which the transmission capacity is extended.

FIG. 4 shows a schematic configuration of an optical transceiver 100A shown in FIG. 3.

FIG. 5 shows a stage where 10 Gbps, 25 Gbps, 50 Gbps, and 100 Gbps systems coexist in one scenario in which the transmission capacity is extended.

FIG. 6 shows a schematic configuration of an optical transceiver 100B shown in FIG. 5.

FIG. 7 is a schematic timing diagram for illustrating a part of signals that are input to and output from an optical transceiver.

FIG. 8 is a plan view schematically showing an example of arrangement of a plurality of electrodes on the upper surface of a host interface.

FIG. 9 is a plan view schematically showing an example of arrangement of a plurality of electrodes on the lower surface of the host interface.

FIG. 10 is a schematic cross-sectional view showing an example of a connector mounted on a host board.

FIG. 11 shows an example of arrangement of a plurality of terminals on the host board.

FIG. 12 is a circuit diagram showing schematic configurations of TTL and CML.

FIG. 13 schematically shows connection between the optical transceiver and the host board in a steady state.

FIG. 14 schematically shows a state during hot swapping of the optical transceiver and the host board.

FIG. 15 illustrates whether interfaces of the same type or different types can be connected or not in the form of a table.

FIG. 16 shows a configuration in one form for tolerating electrical impact during hot swapping of the optical transceiver.

FIG. 17 shows a configuration in another form for tolerating electrical impact during hot swapping of the optical transceiver.

FIG. 18 is a block diagram showing a schematic configuration relating to OLT data transmission according to the present embodiment.

FIG. 19 is a plan view schematically showing an example of arrangement of a plurality of electrodes on the upper surface of a host interface of an optical transceiver (SFP-DD) according to an embodiment.

FIG. 20 is a plan view schematically showing an example of arrangement of a plurality of electrodes on the lower surface of the host interface of the optical transceiver (SFP-DD) according to an embodiment.

FIG. 21 is a plan view schematically showing another example of arrangement of a plurality of electrodes on the upper surface of the host interface.

FIG. 22 is a plan view schematically showing another example of arrangement of a plurality of electrodes on the lower surface of the host interface.

### DETAILED DESCRIPTION

[Problem to be Solved by the Present Disclosure]

It is expected that, as the number of signals transmitted between an optical module and a host board increases, the number of electrodes of the optical module increases. It is therefore expected that improvements in arrangement of the electrodes are further necessary.

An object of the present disclosure is to provide a pluggable optical module having electrodes arranged in accordance with a new layout, and a host board to be connected to the pluggable module.

[Advantageous Effect of the Present Disclosure]

According to the foregoing, a pluggable optical module having electrodes arranged in accordance with a new layout, and a host board to be connected to this pluggable optical module can be provided.

[Description of Embodiments]

First, manners in which the present invention is implemented are described one by one.

(1) A pluggable optical module according to an aspect of the present invention includes: a circuit board insertable to and removable from a connector of a host board; a plurality of first electrodes arranged in a first direction on a first surface of the circuit board, the first direction crossing an insert direction in which the pluggable optical module is to be inserted; and a plurality of second electrodes arranged in the first direction on the first surface of the circuit board, the second electrodes being arranged on a host board side associated with the host board, with respect to the plurality of first electrodes. The plurality of first electrodes and the plurality of second electrodes are arranged in accordance with a layout rule for tolerating electrical impact occurring when at least one of a plurality of terminals of the connector that are configured to be brought into contact with respective first electrodes of the plurality of first electrodes contacts any electrode of the plurality of second electrodes.

According to the above-described configuration, a pluggable optical module having electrodes arranged in accordance with a new layout can be provided. For example, the optical module may be inserted to/removed from the host board while the host board is in operation. When an optical module having two rows of electrodes is inserted to or removed from a cage, a state of incomplete connection in which a host-side electrode of the optical module contacts a module-side pin in the cage may be generated. In such a state of incomplete connection, electrical impact due to a difference in voltage level may occur. A plurality of first electrodes and a plurality of second electrodes can be arranged in accordance with a layout rule based on a layout for tolerating electrical impact, to thereby enhance the degree of freedom in assigning signals to a plurality of electrodes.

(2) Preferably, the plurality of first electrodes are assigned with signals to be transmitted at a first transmission speed. The plurality of second electrodes are assigned with signals to be transmitted at a second transmission speed different from the first transmission speed.

According to the foregoing, arrangement of lines for connecting circuits to the plurality of first electrodes and the plurality of second electrodes can be prevented from being complicated.

(3) Preferably, the plurality of second electrodes include an input electrode assigned with a control signal to be input from the host board to the pluggable optical module. The pluggable optical module further includes: a control circuit that receives the control signal; and a series resistor connected in series between the input electrode and the control circuit.

According to the foregoing, the probability that the control circuit is damaged due to the state of incomplete connection can be reduced.

(4) Preferably, the plurality of second electrodes include an output electrode assigned with a control signal to be output from the pluggable optical module to the host board. The pluggable optical module further includes: a control circuit that outputs the control signal; and an output stage transistor including a collector or a drain connected to the output electrode. The output stage transistor forms an open collector circuit or an open drain circuit.

According to the foregoing, the probability that the control circuit is damaged due to the state of incomplete connection can be reduced.

(5) A host board according to an aspect of the present invention includes a connector attachable to and detachable from a host interface of a pluggable optical module. The host interface of the pluggable optical module has a surface on which a plurality of first electrodes are arranged in a row and a plurality of second electrodes are arranged in a row. The plurality of second electrodes are arranged on a host board side associated with the host board, with respect to the plurality of first electrodes. The host board further includes a circuit board on which the connector is mounted. The connector includes: a plurality of first terminals to be brought into contact with respective first electrodes of the plurality of first electrodes of the host interface; and a plurality of second terminals to be brought into contact with respective second electrodes of the plurality of second electrodes of the host interface. The plurality of first terminals and the plurality of second terminals are arranged on the connector in accordance with a pin assignment for tolerating electrical impact that may occur when at least one of the plurality of first terminals of the connector contacts any electrode of the plurality of second electrodes of the host interface.

According to the foregoing, a host board that can be coupled to a pluggable optical module having electrodes arranged in accordance with a new layout can be provided.

(6) Preferably, the plurality of first terminals are assigned with signals to be transmitted at a first transmission speed. The plurality of second terminals are assigned with signals to be transmitted at a second transmission speed different from the first transmission speed.

According to the foregoing, arrangement of lines on the host board for connecting circuits to the plurality of first electrodes and the plurality of second electrodes can be prevented from being complicated.

(7) Preferably, the plurality of second terminals include an input terminal assigned with a control signal to be input from the pluggable optical module to the host board. The host board further includes: a control circuit that receives the control signal; and a pull-up resistor connected between the input terminal and a positive voltage.

According to the foregoing, the probability that the control circuit is damaged due to the state of incomplete connection can be reduced.

[Details of Embodiments]

Embodiments of the present invention are described hereinafter with reference to the drawings. In the drawings, the same or corresponding parts are denoted by the same reference characters, and description thereof is not repeated.

A pluggable optical module according to this embodiment is configured to transmit and receive an electrical signal and/or an optical signal at various data rates per second. The data rates per second include, but not limited to, data rates of 1 gigabit per second (G), 10 G, 25 G, 100 G, and 400 G. The terms such as “1 G”, “10 G”, “25 G”, “100 G” and “400 G” or terms similar to them that are used herein represent rounded numbers of general signal rates, and have a meaning commonly understood by those skilled in the art.

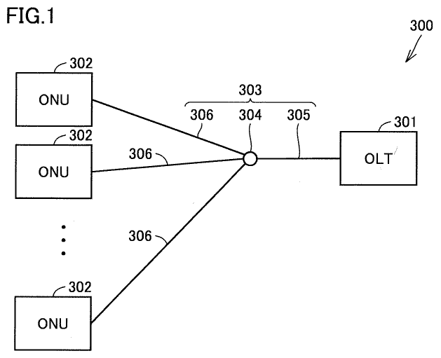

In the following, a PON (Passive Optical Network) system is illustrated by way of example, as an optical communication system according to an embodiment. FIG. 1 is a schematic diagram of a PON system according to an embodiment. PON system 300 includes an OLT (Optical Line Terminal) 301, an ONU (Optical Network Unit) 302, a PON line 303, and an optical splitter 304.

OLT 301 is placed in a building of a telecommunications carrier, for example. OLT 301 is mounted with a host board (not shown). To the host board, an optical transceiver (not shown) that converts an electrical signal to an optical signal and vice versa is connected. The optical transceiver is a pluggable optical module attachable to and detachable from the host board.

ONU 302 is placed on the user side. A plurality of ONUs 302 are each connected to OLT 301 through PON line 303.

PON line 303 is an optical communication line formed by an optical fiber. PON line 303 includes a main-line optical fiber 305 and at least one branch-line optical fiber 306. Optical splitter 304 is connected to main-line optical fiber 305 and branch-line optical fiber 306. A plurality of ONUs 302 can be connected to PON line 303. For extending the transmission distance, an optical relay (not shown) may be placed on PON line 303.

An optical signal transmitted from OLT 301 is passed through PON line 303 and split toward a plurality of ONUs 302 by optical splitter 304. In contrast, optical signals transmitted from respective ONUs 302 are combined by optical splitter 304 and passed through PON line 303 to OLT 301. OLT 301 transmits a continuous optical signal. In contrast, ONU 302 transmits a burst optical signal. Optical splitter 304 passively splits an input signal or multiplexes input signals without particularly requiring external power supply.

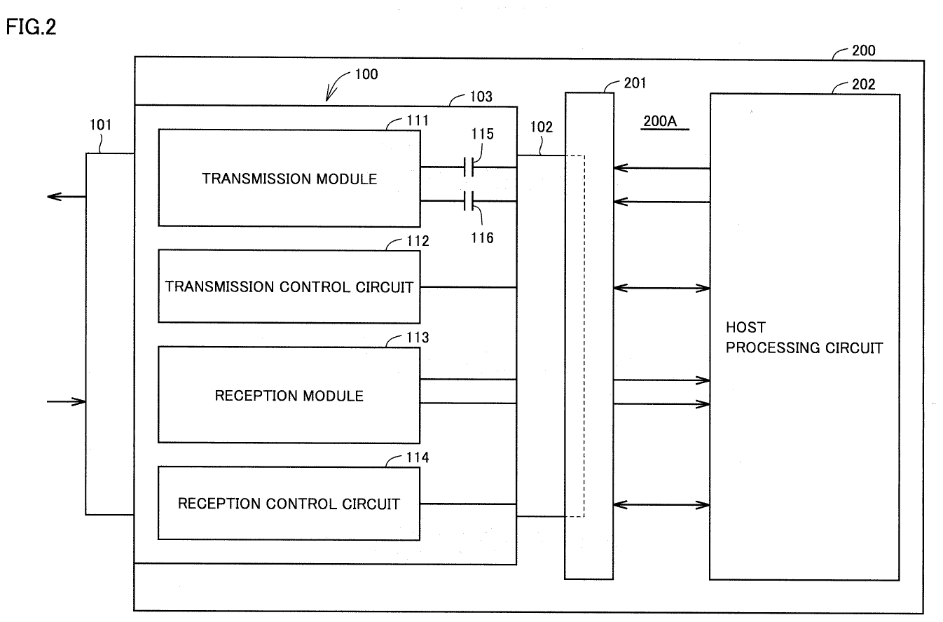

FIG. 2 is a block diagram schematically showing an application including a host board and an optical transceiver. As shown in FIG. 2, host board 200 includes a circuit board 200A, and a connector 201 and a host processing circuit 202 that are mounted on circuit board 200A. Host processing circuit 202 is implemented by a semiconductor integrated circuit such as IC (Integrated Circuit) and LSI (Large Scale Integrated circuit), for example.

Optical transceiver 100 includes an optical interface 101, a host interface 102, and a module main body 103. Host interface 102 is configured to be attachable to and detachable from connector 201 of host board 200. Optical transceiver 100 is thus attachable (pluggable) to/detachable from host board 200. Module main body 103 may include a transmission module 111, a transmission control circuit 112 for controlling transmission module 111, a reception module 113, a reception control circuit 114 for controlling reception module 113, and coupling capacitors 115, 116.

Transmission module 111 receives a differential signal from host board 200 to drive a light-emitting element (typically laser diode) which is not shown. Accordingly, an optical signal (transmission signal) is output from optical interface 101. On host board 200, the differential signal is directly coupled to host processing circuit 202. In optical transceiver 100, the differential signal is AC-coupled to transmission module 111 by coupling capacitors 115, 116.

Reception module 113 includes a light-receiving element (typically photodiode) which is not shown. The light-receiving element receives a burst optical signal passed through PON line 303 (see FIG. 1) and converts the burst optical signal into a current signal. Reception module 113 includes a TIA (Transimpedance Amplifier), for example, converts the current signal into a voltage signal and amplifies the voltage signal. Reception module 113 transmits the voltage signal in the form of a differential signal to host board 200. The differential signal is output by DC coupling from optical transceiver 100.

Respective functions of transmission module 111 and reception module 113 are not limited to the above-described functions. For example, the function of transmission module 111 includes linear equalization and correction. Likewise, the function of reception module 113 includes reproduction of a signal.

Transmission control circuit 112 and reception control circuit 114 control transmission module 111 and reception module 113, respectively. Transmission control circuit 112 and reception control circuit 114 transmit and receive signals to and from host board 200.

Host interface 102 is implemented by an edge portion (card edge) of a circuit board on which a plurality of electrodes are arranged. In this embodiment, a plurality of electrodes are arranged on each of two surfaces of the circuit board. In the following, one of the two surfaces of the circuit board is referred to as “upper surface” and the surface opposite to the upper surface is referred to as “lower surface.” A plurality of electrodes may be arranged on only one of the two surfaces of the circuit board. The term “first surface” refers to a surface on which the plurality of electrodes are arranged. For a circuit board with electrodes arranged on both of the two surfaces, the term “first surface” refers to either one of the two surfaces.

As a high-speed PON system, a wavelength multiplexing PON system has been studied that assigns a plurality of wavelengths to upstream signals or downstream signals, and multiplexes upstream signals or downstream signals with the plurality of wavelengths to configure the upstream or downstream signals. For example, for a 100 Gbps class PON, four wavelengths are assigned to 25 Gbps signals each having a transmission capacity of 25 Gbps per wavelength, for each of upstream and downstream traffics, so as to multiplex the upstream and downstream signals with these wavelengths. In such a PON system, a newer-generation system (100 Gbps system, for example) and an older-generation system (1 Gbps or 10 Gbps system, for example) can coexist. As a scenario for introducing a 100 Gbps class PON, a scenario may be devised in which the transmission capacity is extended (upgraded) step by step.

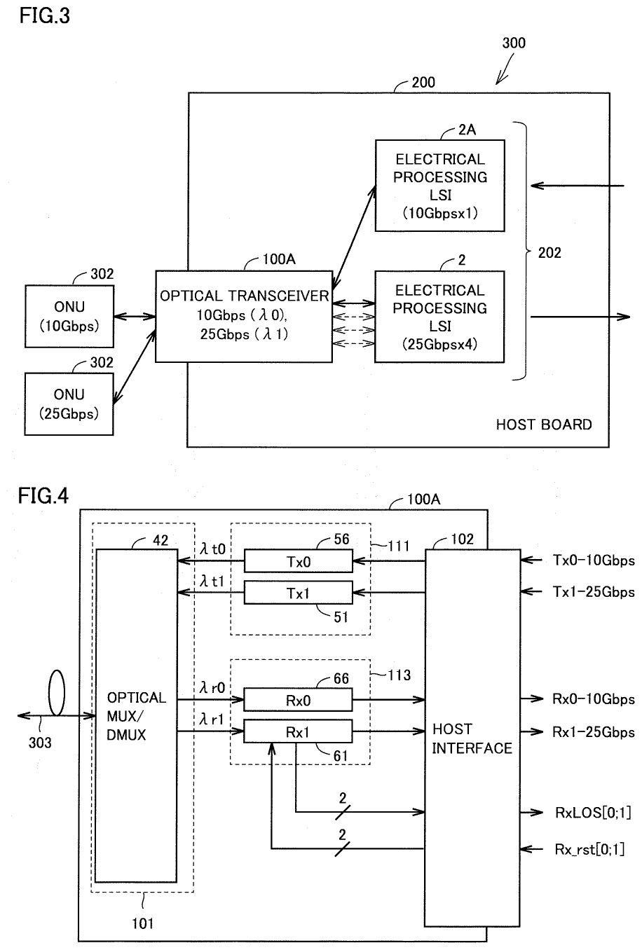

FIG. 3 shows a stage where a 10 Gbps system and a 25 Gbps system coexist in one scenario in which the transmission capacity is extended. As shown in FIG. 3, a 10 Gbps ONU 302 and a 25 Gbps ONU 302 are introduced in a PON system 300. On a host board 200, an optical transceiver 100A and a host processing circuit 202 are mounted.

Optical transceiver 100A is an implemented example of optical transceiver 100 shown in FIG. 2. Optical transceiver 100A is capable of supporting both the transmission capacities of 10 Gbps (wavelength λ0) and 25 Gbps (wavelength λ1). Host processing circuit 202 includes an electrical processing LSI 2A capable of transmission at 10 Gbps×1 and an electrical processing LSI 2 capable of transmission at 25 Gbps×4.

As to notation for wavelengths, “λt” represents transmission wavelength and “λr” represents reception wavelength. Further, “λt” and “λr” are represented collectively as “λ”. For example, the wavelength λ0 shown in FIG. 3 collectively represents wavelengths λt0 and λr0 as described later herein.

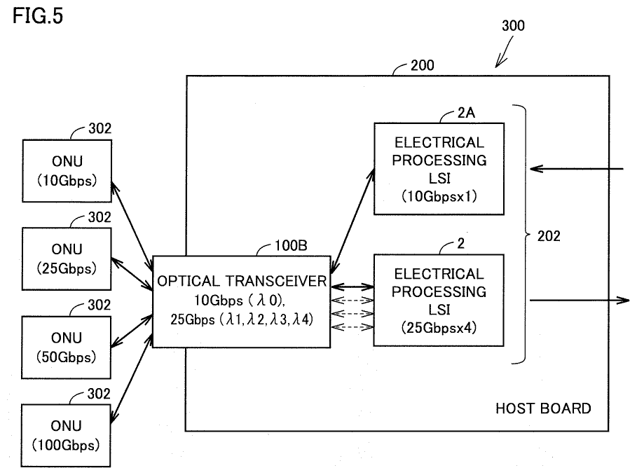

FIG. 4 shows a schematic configuration of optical transceiver 100A shown in FIG. 3. As shown in FIG. 4, optical transceiver 100A supports one 10 Gbps lane and one 25 Gbps lane. Optical transceiver 100A includes optical transmission units 51, 56, optical reception units 61, 66, an optical interface 101, and a host interface 102.

Optical transmission units 51, 56 may be included in transmission module 111 shown in FIG. 2, for example. Optical transmission unit 56 receives, from host interface 102, a 10 Gbps transmission signal (represented as “Tx0-10 Gbps”) in the form of an electrical signal, and outputs the transmission signal with wavelength λt0 in the form of an optical signal. Optical transmission unit 51 receives, from host interface 102, a 25 Gbps transmission signal (represented as “Tx1-25 Gbps”) in the form of an electrical signal, and outputs this signal in the form of an optical signal with wavelength λt1.

Optical reception units 66, 61 may be included in reception module 113 shown in FIG. 2. Optical reception unit 66 receives an optical signal (10 Gbps reception signal) with wavelength λr0 from optical interface 101, and outputs the reception signal in the form of an electrical signal (represented as “Rx0-10 Gbps”) from host interface 102. Optical reception unit 61 receives an optical signal (25 Gbps reception signal) with wavelength λr1 from optical interface 101, and outputs the reception signal in the form of an electrical signal (represented as “Rx1-25 Gbps”) from host interface 102.

Optical interface 101 includes an optical wavelength multiplexer/demultiplexer (MUX/DMUX) 42. Optical wavelength multiplexer/demultiplexer 42 is optically connected to PON line 303. Optical wavelength multiplexer/demultiplexer 42 outputs, to PON line 303, the optical signal with wavelength λt1 from optical transmission unit 51 and the optical signal with wavelength λt0 from optical transmission unit 56. Optical wavelength multiplexer/demultiplexer 42 outputs an optical signal with wavelength λr1 from PON line 303 to optical reception unit 61, and outputs an optical signal with wavelength λr0 from PON line 303 to optical reception unit 66. Optical wavelength multiplexer/demultiplexer 42 can multiplex the optical signal with wavelength λt1 and the optical signal with wavelength λt0 by means of wavelength multiplexing. Further, optical wavelength multiplexer/demultiplexer 42 can demultiplex the optical signal with wavelength λr1 and the optical signal with wavelength λr0 that have been multiplexed by means of wavelength multiplexing.

Optical reception units 66, 61 output respective reception detection signals representing their reception statuses to optical transceiver 100A through host interface 102. Optical reception units 66, 61 receive respective reset signals for resetting reception of reception units 66, 61 from the outside of optical transceiver 100A through host interface 102. In FIG. 4, the expression “RxLOS[0;1]” collectively represents respective reception detection signals that are output from optical reception units 66, 61, and the expression “Rx_rst[0;1]” collectively represents respective reset signals that are input to optical reception units 66, 61.

FIG. 5 shows a stage where 10 Gbps, 25 Gbps, 50 Gbps, and 100 Gbps systems coexist in one scenario in which the transmission capacity is extended. As compared with FIG. 3, an optical transceiver 100B instead of optical transceiver 100A is mounted on host board 200. Optical transceiver 100A is removed from host board 200 and optical transceiver 100B is mounted on host board 200. In this way, the configuration shown in FIG. 5 can be implemented.

Optical transceiver 100B is an implemented example of optical transceiver 100 shown in FIG. 2. Optical transceiver 100B is an optical transceiver adapted to 10 Gbps×1 wavelength (wavelength λ0) and 25 Gbps×4 wavelengths (λ1, λ2, λ3, λ4).

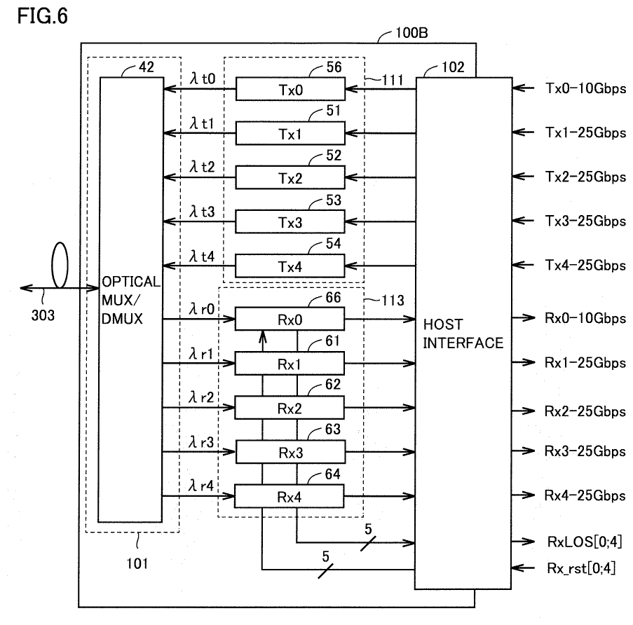

FIG. 6 shows a schematic configuration of optical transceiver 100B shown in FIG. 5. Optical transceiver 100B supports one 10 Gbps lane and four 25 Gbps lanes. Optical transceiver 100B has a configuration additionally including optical transmission units 52, 53, 54 and optical reception units 62, 63, 64 relative to the configuration shown in FIG. 4.

Optical transmission units 52, 53, 54 receive, from host interface 102, 25 Gbps transmission signals (represented as “Tx2-25 Gbps”, “Tx3-25 Gbps”, “Tx4-25 Gbps”) in the form of electrical signals. Optical transmission units 52, 53, 54 output optical signals with wavelengths λt2, λt3, λt4, respectively.

Optical reception units 62, 63, 64 receive, from optical interface 101, optical signals with wavelengths λr2, λr3, λr4, respectively. Optical reception units 62, 63, 64 output, from host interface 102, the received signals in the faun of electrical signals (“Rx2-25 Gbps”, “Rx3-25 Gbps”, “Rx4-25 Gbps”). λt0 to λt4 are wavelengths different from each other, and λr0 to λr4 are also wavelengths different from each other.

Optical reception units 66 and 61 to 64 output respective reception detection signals (represented collectively as RxLOS[0;4]) representing a reception status. Further, optical reception units 66 and 61 to 64 receive respective reception reset signals (represented collectively as Rx_st[0;4]) for resetting reception.

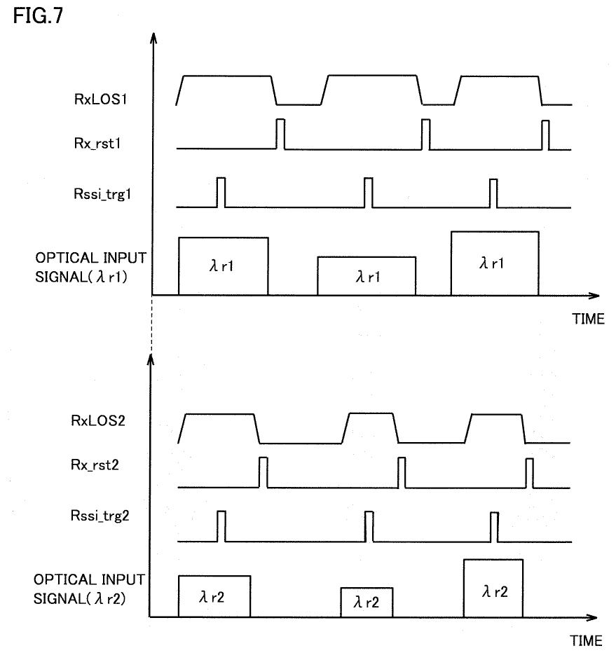

FIG. 7 is a schematic timing diagram for illustrating a part of signals that are input to and output from an optical transceiver. As signals relevant to reception at 100 Gbps, reception detection signals RxLOS1, RxLOS2, reset signals Rx_rst1, Rx_rst2, reception strength (RSSI: Received Signal Strength Indicator) trigger signals Rssi_trg1, Rssi_trg2, and optical input signal (λr1) and optical input signal (λr2) are shown. Reception detection signal RxLOS1, reset signal Rx_rst1, reception strength trigger signal Rssi_trg1, and optical input signal (λr1) are signals relevant to optical reception unit 61. Reception detection signal RxLOS2m, reset signal Rx_rst2, reception strength trigger signal Rssi_trg2, and optical input signal (λr2) are signals relevant to optical reception unit 62.

Reception detection signals RxLOS1, RxLOS2 are signals that are output from the optical transceiver to indicate whether there is an optical input signal by a level of a logic such as TTL (Transistor-transistor-logic). Reset signals Rx_rst1, Rx_rst2 are control signals that are input to the optical transceiver to reset the optical reception units after receiving (or before receiving) a burst signal. The reception strength trigger signal is a control signal that is input to the optical transceiver to indicate the timing to monitor the optical reception level of the burst signal. For example, during a period in which the logic level of the reception strength trigger signal is high (High), the reception strength is monitored.

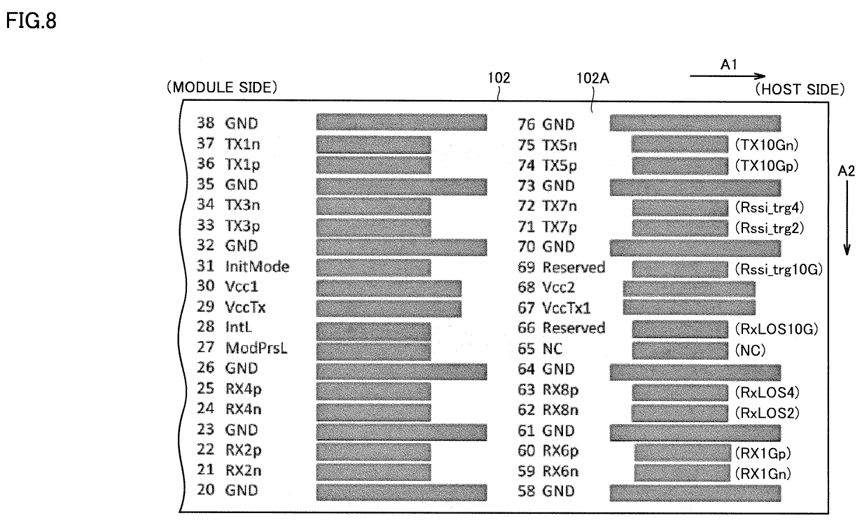

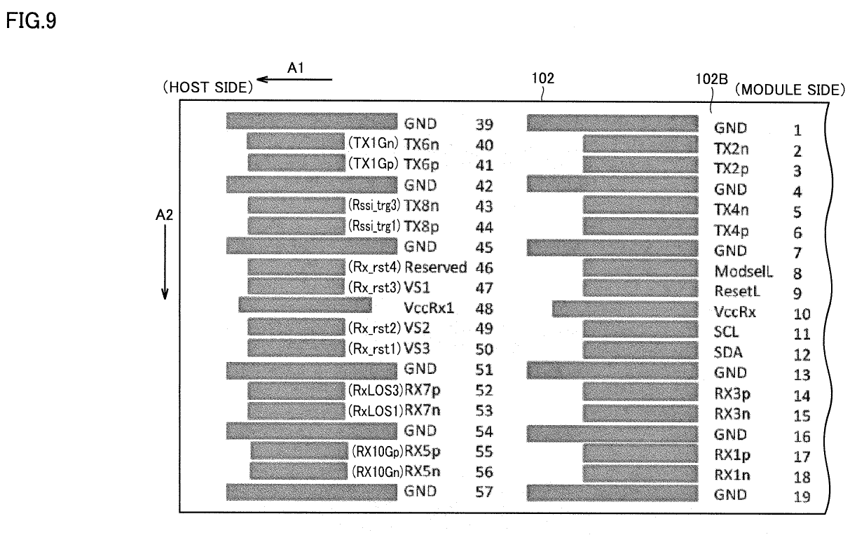

FIG. 8 is a plan view schematically showing an example of arrangement of a plurality of electrodes on the upper surface of host interface 102. FIG. 8 shows an example of arrangement of a plurality of electrodes on the upper surface as seen from above the upper surface. FIG. 9 is a plan view schematically showing an example of arrangement of a plurality of electrodes on the lower surface of host interface 102. FIG. 9 shows an example of arrangement of a plurality of electrodes on the lower surface as seen from below the lower surface. The term “electrode” may be interchanged with a term such as “terminal” or “pad” commonly understood by those skilled in the art.

In an embodiment, optical transceiver 100 has a form factor complying with the QSFP-DD. On each of the upper surface and the lower surface of host interface 102, a plurality of electrodes are arranged in two rows. The number of electrodes and assignment of signals to respective electrodes may comply with the QSFP-DD specification (see “QSFP-DD Specification for QSFP Double Density 8× Pluggable Transceiver Rev 2.0”). In this specification, the row on the module (optical transceiver) side is called “first row” and the row on the host side is called “second row.” The order of “first” and “second” is given for the sake of convenience and does not intend to limit the embodiment. In this embodiment, the direction of “row” refers to direction A2 crossing (typically orthogonal to) the insert direction (direction A1) in which optical transceiver 100 is inserted to connector 201.

In accordance with an embodiment, a plurality of terminals in the first row are assigned to 100G-PON signals, and some of a plurality of terminals in the second row are assigned to low-speed (older generation) signals and burst control signals. As shown in FIGS. 8 and 9, some of the terminals in the second row on upper surface 102A are assigned, for example, with 10 Gbps transmission signals (TX10Gn, TX10Gp), reception strength trigger signals (Rssi_trg4, Rssi_trg2, Rssi_trg10G), reception detection signals (RxLOS10G, RxLOS4, RxLOS2), and 1 Gbps reception signals (RX1Gp, RX1Gn). Some of the terminals in the second row on lower surface 102B are assigned with 1 Gbps transmission signals (TX1Gp, TX1Gn), reception strength trigger signals (Rssi_trg1, Rssi_trg3), reception reset signals (Rx_rst1 to Rx_rst4), reception detection signals (RxLOS1, RxLOS3), and 10 Gbps reception signals (RX10Gn, RX10Gp).

The aforementioned transmission signals and reception signals are differential signals, and “p” and “n” each included in a symbol representing a differential signal represents the signal polarity. As described above, the reception detection signal, the reception strength trigger signal, and the reception reset signal are control signals that reception control circuit 114 (see FIG. 2) of optical transceiver 100 transmits to host board 200, or that reception control circuit 114 receives from host board 200.

In this embodiment, the transmission speed of signals assigned to electrodes in the first row differs from the transmission speed of signals assigned to electrodes in the second row. It should be noted that the aforementioned values of the transmission speed are values according to an example in the present embodiment.

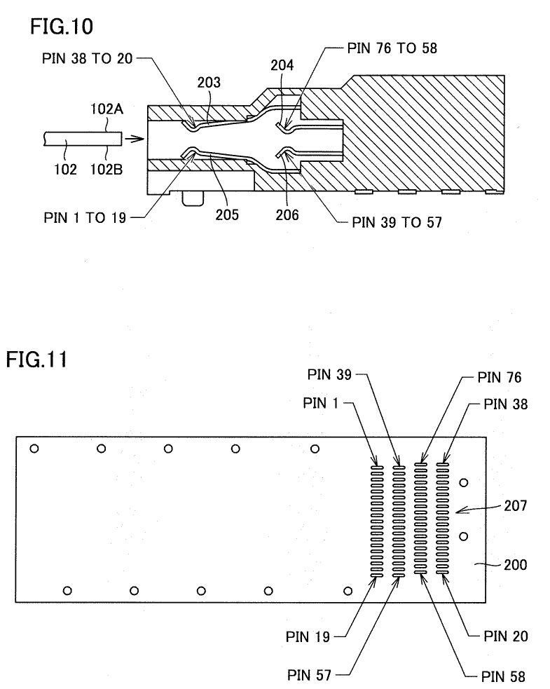

FIG. 10 is a schematic cross-sectional view showing an example of connector 201 mounted on host board 200. Connector 201 has a plurality of pins 203, a plurality of pins 204, a plurality of pins 205, and a plurality of pins 206. The term “pin” may be interchanged with a term such as “terminal” that is commonly understood by those skilled in the art.

Pin numbers (1 to 76) in FIG. 10 are identical to the electrode numbers shown in FIGS. 8 and 9 and the pin numbers in FIG. 11 described later herein. A plurality of pins 203 are to be brought into contact with a plurality of terminals in the first row on upper surface 102A of host interface 102. A plurality of pins 204 are to be brought into contact with a plurality of terminals in the second row on upper surface 102A of host interface 102. A plurality of pins 205 are to be brought into contact with a plurality of terminals in the first row on lower surface 102B of host interface 102. A plurality of pins 206 are brought into contact with a plurality of terminals in the second row on lower surface 102B of host interface 102.

FIG. 11 shows an example of arrangement of a plurality of terminals on the host board. As indicated by pin numbers (1 to 76), a plurality of terminals 207 on host board 200 are associated with a plurality of pins 203 to 206 shown in FIG. 10.

As shown in FIGS. 8 and 9, a plurality of terminals for high-speed signals are arranged on the module side on host interface 102. These terminals can be connected to transmission module 111 and reception module 113 without via holes in between. Accordingly, a high signal quality is easier to ensure. Signal fluctuations can be lessened and signal losses can be reduced. Further, the interconnection layout on the host board 200 side can be simplified.

Moreover, an Ethernet® transceiver that uses module-side terminals only can be plugged into the host board. Accordingly, the port can be used for both PON and point-to-point network.

As shown in FIG. 10, the row of a plurality of pins 203 and the row of a plurality of pins 204 are arranged along the direction in which host interface 102 is inserted/removed. Therefore, while host interface 102 is being inserted into connector 201 or host interface 102 is being removed from connector 201, a state is generated in which a plurality of terminals in the second row (host side) on host interface 102 are brought into contact with pins (a plurality of pins 203, 205) in a first row of connector 201.

Referring back to FIG. 8, the electrodes numbered 62, 63 are assigned with reception detection signals (RxLOS2, RxLOS4), and the electrodes numbered 24, 25 are assigned with 100 Gbps reception signals (RX4n, RX4p). The electrodes numbered 62, 63 are connected to output circuits for control signals, and the electrodes numbered 24, 25 are connected to output circuits for reception signals. On the host board 200 side, the pins numbered 24, 25 are connected to input circuits for reception signals.

When host interface 102 of optical transceiver 100 is inserted to and removed from connector 201 of host board 200, the pins numbered 24, 25 on the host board 200 side may be brought into contact with the electrodes numbered 62, 63 of optical transceiver 100. At this time, the two circuits connected to each other may differ from each other in voltage level. Electrical impact due to the connection of the two circuits at different voltage levels may cause one or both of optical transceiver 100 and the host board to fail.

In another example, the electrodes numbered 71, 72 are assigned with reception strength trigger signals (Rssi_trg2, Rssi_trg4), and the electrodes numbered 33, 34 are assigned with 100 Gbps transmission signals (TX3p, TX3n). The electrodes numbered 71, 72 are connected to input circuits for control signals, and the electrodes numbered 33, 34 are connected to input circuits for control signals. On the host board 200 side, the pins numbered 33, 34 are connected to output circuits for transmission signals. While host interface 102 of optical transceiver 100 is being inserted to and removed from connector 201 of host board 200, the pins numbered 33, 34 on the host board 200 side may be brought into contact with the electrodes numbered 71, 72 of optical transceiver 100. In this case as well, the two circuits connected to each other may differ from each other in voltage level. Thus, electrical impact due to the connection of the two circuits at different voltage levels may cause one or both of optical transceiver 100 and the host board to fail.

For the optical transceiver, an interface for use with high-speed signals called CML (Current Mode Logic) is generally used for output of reception signals from the optical transceiver and reception of transmission signals from the host. In contrast, for the optical transceiver, an interface called TTL is generally used for input and output of control signals.

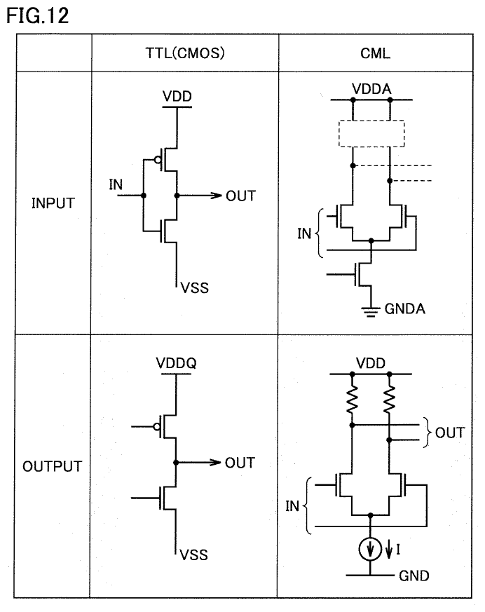

FIG. 12 is a circuit diagram showing schematic configurations of the TTL and the CML. As shown in FIG. 12, in the case of the TTL, each of the input circuit and the output circuit is configured in the form of a CMOS (Complementary Metal Oxide Semiconductor) circuit, for example. The magnitude of power supply voltage VDD with respect to source voltage VSS is 3.3 V, for example. In the case of the CML, the input circuit and the output circuit are each configured in the form of a differential circuit including two N channel MOSFETs, for example. The magnitude of power supply voltage VDDA for the input circuit and power supply voltage VDD for the output circuit depend on the specification of the IC. For example, power supply voltage VDDA and power supply voltage VDD fall in a range from 1.0 to 3.3 V, for example. Aforementioned power supply voltages VDDA, VDD are determined with respect to ground GNDA and ground GND, respectively.

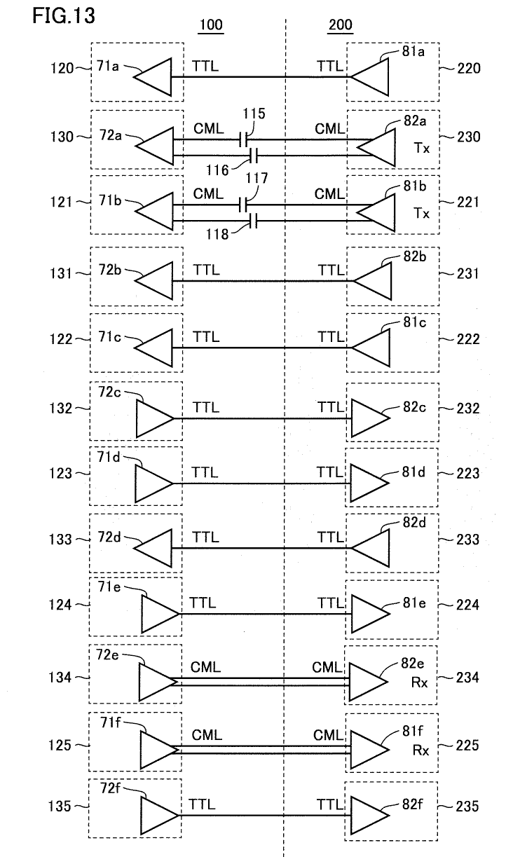

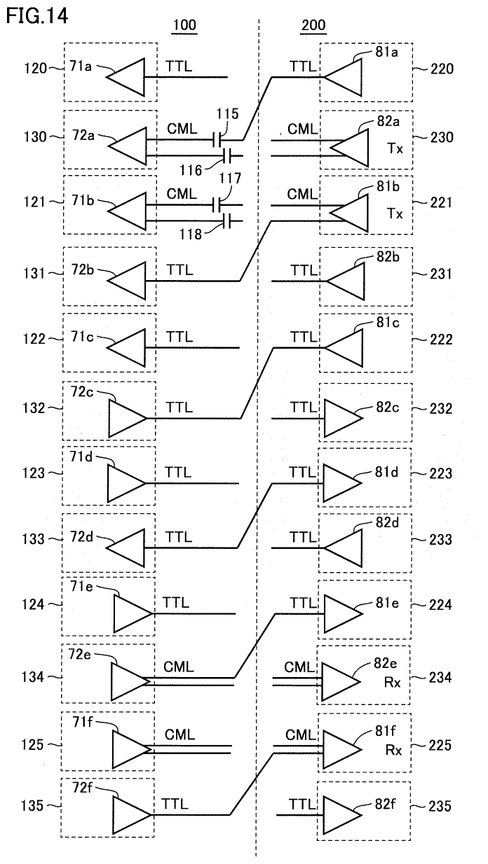

FIG. 13 shows a schematic example of connection between the optical transceiver and the host board in a steady state. FIG. 14 shows a schematic example of a state during hot swapping of the optical transceiver and the host board. In FIGS. 13 and 14 each, an exemplary configuration is shown for the sake of understanding of the principle of the present embodiment. It should be noted that in the description regarding FIGS. 13 and 14, consistency with the pin assignment shown in FIGS. 8 to 11 is not necessarily required.

In the schematic examples shown in FIGS. 13 and 14, optical transceiver 100 includes control circuits 120, 131, 122, 132, 123, 133, 124, 135, transmission circuits 130, 121, and reception circuits 134, 125. Control circuits 120, 131, 122, 132, 123, 133, 124, 135 may be integrated into less than eight control circuits. Control circuits 120, 122, 123, 124, transmission circuit 121, and reception circuit 125 are each connected to a corresponding electrode (not shown) in the first row on the circuit board (host interface 102) of optical transceiver 100. Meanwhile, transmission circuit 130, control circuits 131, 132, 133, 135, and reception circuit 134 are each connected to a corresponding electrode (not shown) in the second row on host interface 102.

Control circuits 120, 131, 122, 133 include input circuits 71a, 72b, 71c, 72d (TTL), respectively. Control circuits 132, 123, 124, 135 include output circuits 72c, 71d, 71e, 72f (TTL), respectively. Transmission circuits 130, 121 include input circuits 72a, 71b (CML), respectively. Reception circuits 134, 125 include output circuits 72e, 71f (CML), respectively. The expressions “(TTL)” and “(CML)” each represent a type of the interface.

Host board 200 includes control circuits 220, 231, 222, 232, 223, 233, 224, 235, transmission circuits 230, 221, and reception circuits 234, 225. Control circuits 220, 222, 223, 224, transmission circuit 221, and reception circuit 225 are each connected to a corresponding terminal (not shown) in the first row (module side) of connector 201 of host board 200. Transmission circuit 230, control circuits 231, 232, 233, 235, and reception circuit 234 are each connected to a corresponding electrode (not shown) in the second row (host side) of connector 201 of host board 200.

Control circuits 220, 231, 222, 233 include output circuits 81a, 82b, 81c, 82d (TTL), respectively. Control circuits 232, 223, 224, 235 include input circuits 82c, 81d, 81e, 82f (TTL), respectively. Transmission circuits 230, 221 include output circuits 82a, 81b (CML), respectively. Reception circuits 234, 225 include input circuits 82e, 81f (CML), respectively.

In a steady state, each input circuit of optical transceiver 100 is connected correctly to a corresponding output circuit of host board 200, and each output circuit of optical transceiver 100 is connected correctly to a corresponding input circuit of host board 200. In other words, an output circuit and an input circuit of the same type are connected to each other.

Reception circuits 134, 125 of optical transceiver 100 each output a reception signal to host board 200. The reception signal is a PON upstream burst signal, and therefore, the reception signal from reception circuit 134 and the reception signal from reception circuit 125 are coupled respectively to reception circuits 234, 225 on the host board 200 side by DC coupling. Meanwhile, to each of transmission circuits 230, 221 of host board 200, a transmission signal is coupled directly. The transmission signal from transmission circuit 230 is AC-coupled to input circuit 72a of transmission circuit 130 through coupling capacitors 115, 116 in optical transceiver 100. Likewise, the transmission signal from transmission circuit 221 is AC-coupled to input circuit 71b of transmission circuit 121 through coupling capacitors 117, 118 in optical transceiver 100.

During hot swapping of optical transceiver 100, the electrodes in the first row on the circuit board (host interface 102) of optical transceiver 100 are open. Further, the electrodes in the second row on the circuit board (host interface 102) of optical transceiver 100 are brought into contact with the terminals on the module side (first row) on the host board 200 side. At this time, a state may be generated in which the electrodes on the optical transceiver 100 side and the terminals on the host board 200 side are connected temporarily at different logic levels (voltage levels). For example, the state shown in FIG. 14 may be generated.

One of two inputs of an input circuit (CML) on the optical transceiver 100 side is connected to an output of an output circuit (TTL) on the host board 200 side. According to FIG. 14, one of the two inputs of input circuit 72a (CML) is connected to the output of output circuit 81a (TTL).

An input of an input circuit (TTL) on the optical transceiver 100 side is connected to one of two outputs of an output circuit (CML) on the host board 200 side. According to FIG. 14, the input of input circuit 72b (TTL) is connected to one of the two outputs of output circuit 81b (CML).

An output of an output circuit (TTL) on the optical transceiver 100 side is connected to an output of an output circuit (TTL) on the host board 200 side. According to FIG. 14, the output of output circuit 72c (TTL) is connected to the output of output circuit 81c (TTL).

An input of an input circuit (TTL) on the optical transceiver 100 side is connected to an input of an input circuit (TTL) on the host board 200 side. According to FIG. 14, the input of input circuit 72d (TTL) is connected to the input of input circuit 81d (TTL).

One of two outputs of an output circuit (CML) on the optical transceiver 100 side is connected to an input of an input circuit (TTL) on the host board 200 side. According to FIG. 14, one of the two outputs of output circuit 72e (CML) is connected to the input of input circuit 81e (TTL).

An output of an output circuit (TTL) on the optical transceiver 100 side is connected to one of two inputs of an input circuit (CML) on the host board 200 side. According to FIG. 14, the output of output circuit 72f (TTL) is connected to one of the two inputs of input circuit 81f (CML).

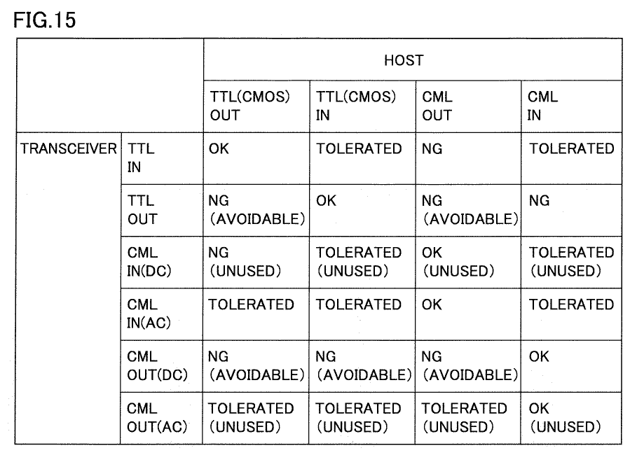

FIG. 15 illustrates whether interfaces of the same type or different types can be connected or not in the form of a table. The expression “OK” indicates that two interfaces can be connected to each other, and the expression “NG” indicates that two interfaces cannot be connected to each other. In the case of an input interface and an output interface that are of the same type, the two interfaces can be connected to each other. Interfaces of different types, respective inputs of interfaces of the same type, or respective outputs of interfaces of the same type may cause electrical impact due to different logic levels.

In this embodiment, as shown in FIG. 8 or 9, a plurality of electrodes are arranged in two rows on each of upper surface 102A and lower surface 102B of host interface 102. When at least one of a plurality of terminals of the connector that are configured to be brought into contact with respective electrodes in the first row on upper surface 102A or lower surface 102B contacts any of the electrodes in the second row on the surface, electrical impact (collision of signals, short circuit, or the like, for example) due to connection of different logic levels may occur (see FIG. 14). In accordance with a layout rule that tolerates such electrical impact, a plurality of electrodes are arranged on each of upper surface 102A and lower surface 102B of host interface 102. Accordingly, the degree of freedom in assigning signals to a plurality of electrodes can be enhanced.

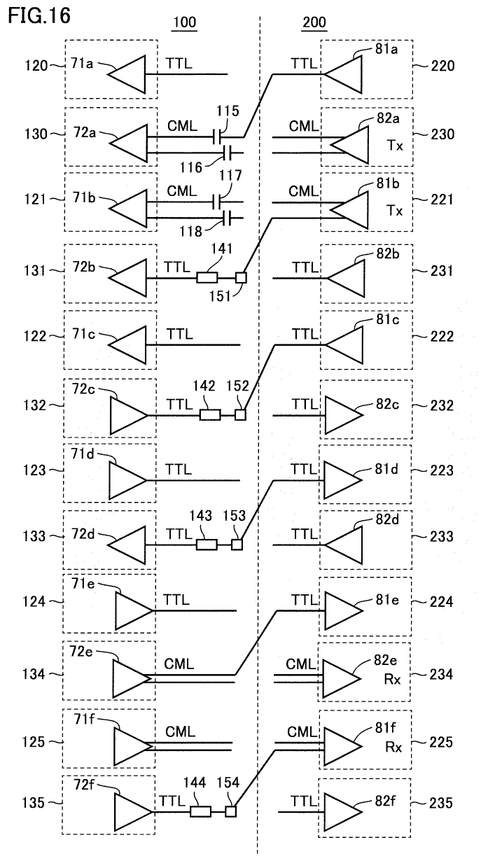

FIG. 16 shows a configuration in one form for tolerating electrical impact during hot swapping of the optical transceiver. As shown in FIG. 16, a series resistor is connected in series between an input circuit (TTL) for a control signal of optical transceiver 100 and a corresponding input electrode. Likewise, a series resistor is connected in series between an output circuit (TTL) for a control signal of optical transceiver 100 and a corresponding output electrode. The resistance value of the series resistor is not particularly limited, but may fall in a range from approximately 100Ω to 1 kΩ, for example. The series resistor can be used to hinder excessively large current from flowing, and reduce the probability that the control circuit is damaged due to the state of incomplete connection between optical transceiver 100 and host board 200.

FIG. 16 exemplarily shows series resistors 141 to 144. Series resistor 141 is connected between the input of input circuit 72b and an input electrode 151. Series resistor 142 is connected between the output of output circuit 72c and an output electrode 152. Series resistor 143 is connected between the input of input circuit 72d and an input electrode 153. Series resistor 144 is connected between the output of output circuit 72f and an output electrode 154.

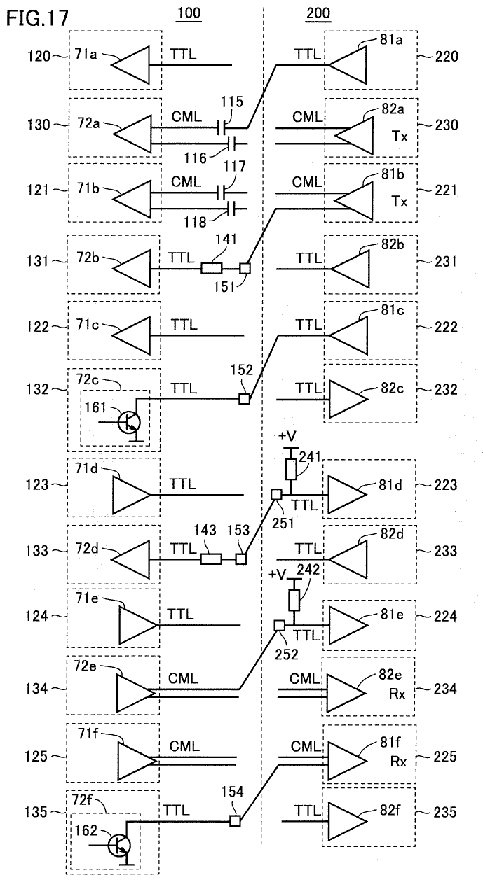

FIG. 17 shows a configuration in another form for tolerating electrical impact during hot swapping of the optical transceiver. As shown in FIG. 17, the output of an output circuit for a control signal of optical transceiver 100 may be an open collector output. The open collector can be used to prevent output of excessively large current and reduce the probability that the control circuit is damaged due to the state of incomplete connection between optical transceiver 100 and host board 200.

FIG. 17 exemplarily shows output-stage transistors 161, 162 for open collector output. Output-stage transistors 161, 162 are each an NPN transistor. The collector of output-stage transistor 161 is connected to output electrode 152. The emitter of output-stage transistor 161 is grounded. The base of output-stage transistor 161 receives a signal from inside control circuit 132. Likewise, the collector of output-stage transistor 162 is connected to output electrode 154. The emitter of output-stage transistor 162 is grounded. The base of output-stage transistor 162 receives a signal from inside control circuit 135.

In FIG. 17, output-stage transistors 161, 162 are each indicated by the symbol for a bipolar transistor. Output-stage transistors 161, 162, however, may be MOSFET. In this case, the term “open collector” can be replaced with “open drain.” If the output stage is an N channel MOSFET, the aforementioned terms “emitter” and “base” can be replaced with “source” and “gate” respectively.

On the host board 200 side, an input circuit for a control signal is connected to an input terminal and also to a pull-up resistor. According to FIG. 17, the input of input circuit 81d is connected to an input terminal 251 and also to a pull-up resistor 241. The input of input circuit 81e is connected to an input terminal 252 and also to a pull-up resistor 242. The pull-up resistor is connected to a voltage (+V) that is a power supply voltage, for example.

The pull-up resistor is placed to face the output circuit. As shown in FIG. 17, the pull-up resistor for the output circuit of optical transceiver 100 is placed on the host board 200 side. The pull-up resistor for the output circuit on the host board 200 side may be placed on the optical transceiver 100 side. Accordingly, in a transient state, namely during hot swapping, the output of the output is high impedance (Hi-Z). Therefore, even when optical transceiver 100 and host board 200 are connected erroneously, the probability that the IC in optical transceiver 100 and host board 200 fail can be reduced.

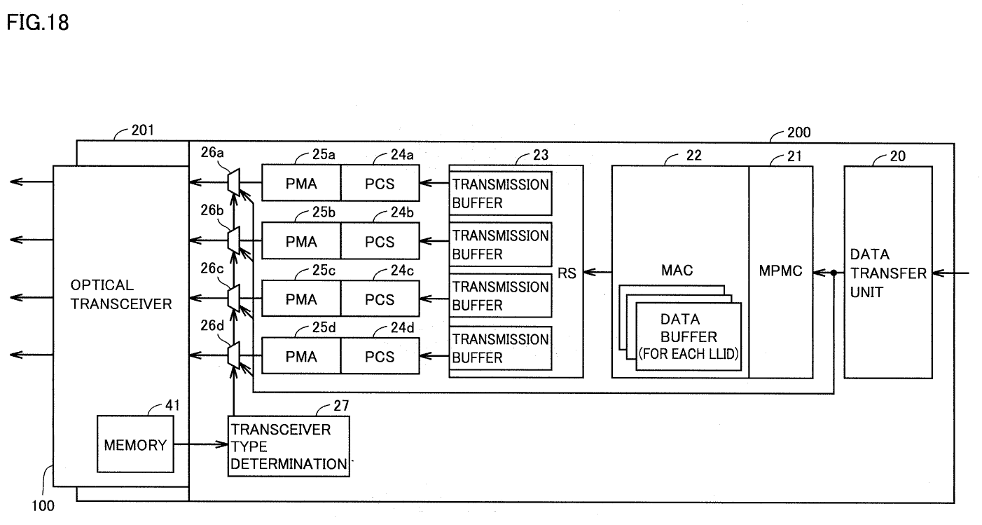

In accordance with the present embodiment, a system appropriate for both a PON transceiver and an Ethernet® transceiver can be established. FIG. 18 is a block diagram showing a schematic configuration relating to OLT data transmission according to the present embodiment. Referring to FIG. 18, host board 200 includes a data transfer unit 20, a multi-point MAC control unit (MPMC) 21, a MAC (Media

Access Control) 22, an RS (Reconciliation Sublayer) 23, PCS (Physical Coding Sublayer) 24a, 24b, 24c, 24d, PMA (Physical Medium Attachment) 25a, 25b, 25c, 25d, multiplexers 26a, 26b, 26c, 26d, and a transceiver type determination unit 27. These components can be mounted on one or a plurality of semiconductor integrated circuits. While FIG. 18 shows four lanes, the number of lanes is not limited.

Data transfer unit 20 performs operations such as relay for MAC frames, concentrating operation for concentrating traffics from a plurality of MACs, and link aggregation for connecting to a higher-order device (not shown) by means of a plurality of lines. MAC 22 gives to an Ethernet® MAC frame an LLID (Logical Link Identifier) indicating a destination of the frame, and converts it into a PON MAC frame. Then, MAC 22 stores data for each LLID in a physical or logical data buffer provided for each LLID.

Multi-point MAC control unit 21 uses information about to which lane the destination of each LLID is connected as well as lane information of the optical transceiver connected to a port that are managed by an MPMC (Multi-Point MAC Control) sublayer to instruct, RS 23, on the amount of data blocks read from each LLID-destined data buffer and which lane is to be used for transmitting the read data blocks.

In accordance with the instruction from multi-point MAC control unit 21, RS 23 reads a data block by a specific unit data length or an integer multiple of the data length, from each LLID-destined data buffer of MAC 22, and allocates, to each data block, an LLID indicating a data destination and a sequence number indicating the order of forming a data structure. RS 23 distributes data blocks to transmission buffers provided for respective lanes. The specific unit data length may be a unit code length of FEC (Forward Error Correction) processed by the PCS.

PCSs 24a to 24d each read a data block from a respective transmission buffer provided for each lane, adjusts the gap between MAC frames, and performs 64B/66B encoding and FEC encoding. PMAs 25a to 25d each perform parallel/serial conversion for interfacing with the optical transceiver.

Received data of a plurality of lanes transmitted from the optical transceiver are subjected to operation such as 64B/66B decoding, FED decoding, descrambling by respective PCSs 24a to 24d, and stored temporarily in a reception buffer (not shown). After receiving data blocks, MAC 22 allocates the data blocks to respective physical or logical LLID-destined data buffers provided for respective LLIDs, in accordance with the LLID (indicating from which ONU the data has been transmitted) given to each data block, and the sequence number indicating the order in the data structure allocated to each data block, and converts a PON MAC frame into an Ethernet® MAC frame. Data transfer unit 20 acquires, from the data buffer, data in the order of sequence numbers indicating the order in the data structure, and performs operations such as relay for MAC frames, concentrating operation for concentrating traffics from a plurality of MACs, and link aggregation for connecting to a higher-order device by means of a plurality of lines.

The aforementioned PON frame conversion is performed if optical transceiver 100 is a PON transceiver. If optical transceiver 100 is an Ethernet® transceiver, the aforementioned PON frame conversion is skipped.

Transceiver type determination unit 27 reads information about the type of optical transceiver 100 that is stored in a memory 41 of optical transceiver 100. This information includes information specifying whether optical transceiver 100 is a PON transceiver or an Ethernet® transceiver. Based on this information, transceiver type determination unit 27 determines the type of optical transceiver 100. Based on the result of the determination, transceiver type determination unit 27 controls multiplexers 26a to 26d. In accordance with a control signal from transceiver type determination unit 27, each of multiplexers 26a to 26d switches to output either a PON frame from a respective PMA or an Ethernet® frame from data transfer unit 20. According to the configuration shown in FIG. 18, the host board connectable to both a 100 GbE optical transceiver and a 100G-EPON optical transceiver, for example, can be provided.

According to the present embodiment, the form factor for optical transceiver 100 is not limited to the QSFP-DD. According to an embodiment, the form factor for the optical transceiver may be the SFP-DD. In accordance with the SFP-DD, 25 Gbps×one wavelength+older generation (10 Gbps or 1 Gbps) may be mounted.

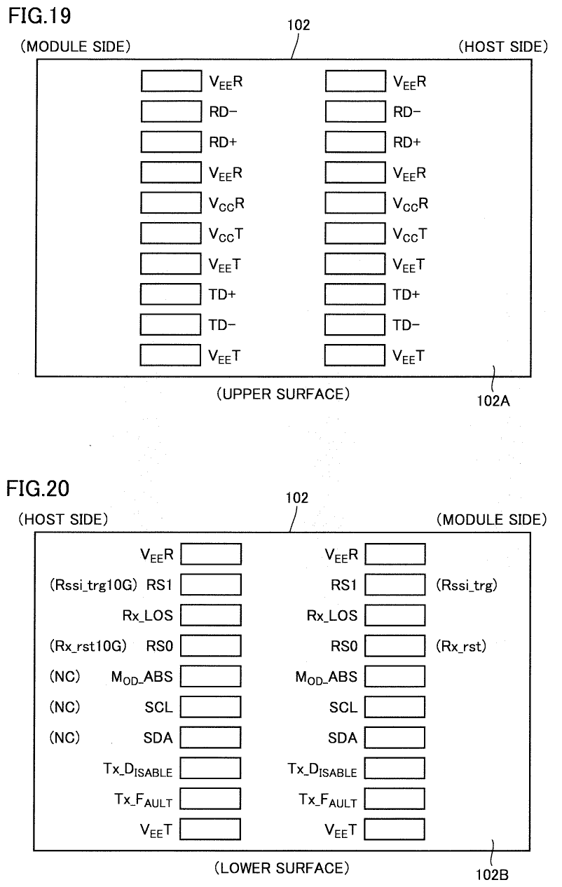

FIG. 19 is a plan view schematically showing an example of arrangement of a plurality of electrodes on the upper surface of host interface 102 of an optical transceiver (SFP-DD) according to an embodiment. FIG. 19 shows an example of arrangement of a plurality of electrodes on the upper surface as seen from above the upper surface. FIG. 20 is a plan view schematically showing an example of arrangement of a plurality of electrodes on the lower surface of host interface 102 of the optical transceiver (SFP-DD) according to an embodiment. FIG. 20 shows an example of arrangement of a plurality of electrodes on the lower surface as seen from below the lower surface. Referring to FIGS. 19 and 20, a plurality of electrodes in a first row (host side) may be assigned to 25G-PON signals, and some of a plurality of electrodes in a second row may be assigned to PON older-generation signals and burst control signals.

In accordance with the present embodiment, the arrangement of a plurality of electrodes on host interface 102 of optical transceiver 100 in accordance with the QSFP-DD is not limited to the one as shown in FIGS. 8 and 9.

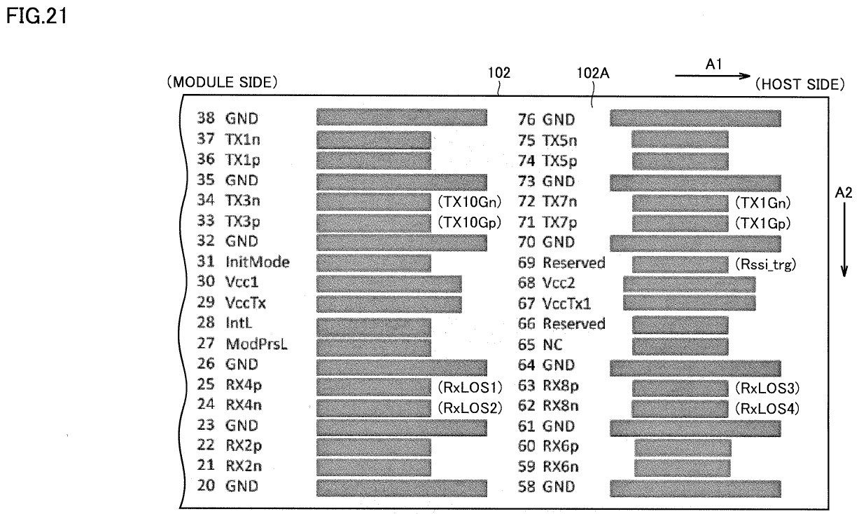

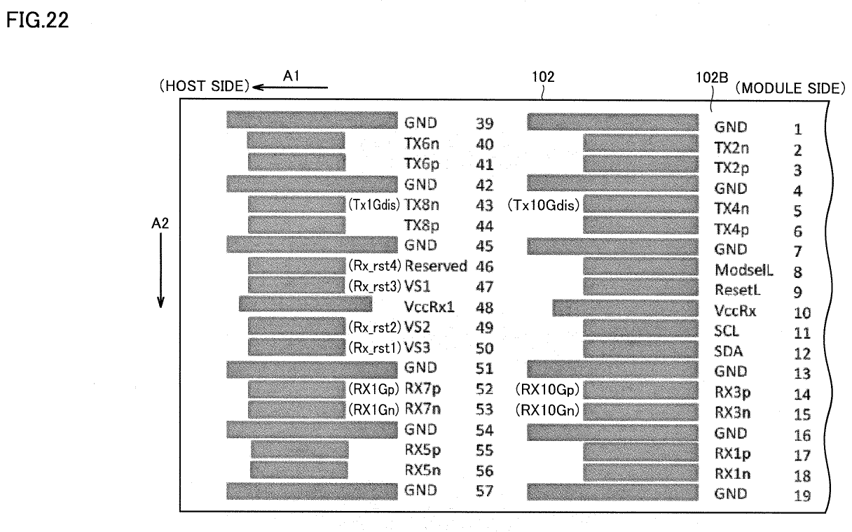

FIG. 21 is a plan view schematically showing another example of arrangement of a plurality of electrodes on the upper surface of host interface 102. FIG. 22 is a plan view schematically showing another example of arrangement of a plurality of electrodes on the lower surface of host interface 102. As compared with FIGS. 8 and 9, in the example of arrangement shown in FIGS. 21 and 22, the arrangement of a plurality of electrodes is determined so as to place an electrode in the first row (module side) and a corresponding electrode in the second row (host side) that are of the same type of electrical interface. For example, on upper surface 102A of host interface 102, the electrodes numbered 24, 25 in the first row are assigned with reception detection signals (RxLOS2, RxLOS1). The electrodes numbered 62, 63 in the second row are also assigned with reception detection signals (RxLOS4, RxLOS3). The electrodes numbered 24, 25, 62, 63 are all electrodes for output of control signals. It is therefore possible to prevent different logic levels from being connected to the electrodes numbered 62, 63 during hot swapping of optical transceiver 100. Likewise, the electrodes numbered 33, 34, 71, 72 are all electrodes for input of transmission (Tx) signals. It is therefore possible to prevent different logic levels from being connected to the terminals numbered 71, 72 during hot swapping of optical transceiver 100. Likewise, as to the arrangement of terminals shown in FIG. 22, the arrangement of a plurality of electrodes is determined so as to place an electrode in the first row (module side) and a corresponding electrode in the second row (host side) that are of the same type of electrical interface.

It should be construed that embodiments disclosed herein are given by way of illustration in all respects, not by way of limitation. It is intended that the scope of the present invention is defined by claims, not by the above embodiments, and encompasses all modifications and variations equivalent in meaning and scope to the claims.

### REFERENCE SIGNS LIST

2, 2A electrical processing LSI 2A; 20 data transfer unit; 21 multi-point MAC control unit (MPMC); 22 MAC (Media Access Control); 23 RS (Reconciliation Sublayer); 24a, 24b, 24c, 24d PCS (Physical Coding Sublayer); 25a, 25b, 25c, 25d PMA (Physical Medium Attachment); 26a, 26b, 26c, 26d multiplexer; 27 transceiver type determination unit; 41 memory; 51, 52, 53, 54, 56 optical transmission unit; 61, 62, 63, 64, 66 optical reception unit; 71a, 71b, 71c, 72a, 72b, 72d, 81d, 81e, 81f, 82c, 82e, 82f input circuit; 71d, 71e, 71f, 72c, 72e, 72f, 81a, 81b, 81c, 82a, 82b, 82d output circuit; 100, 100A, 100B optical transceiver; 101 optical interface; 102 host interface; 102A upper surface; 102B lower surface; 103 module main body; 111 transmission module; 112 transmission control circuit; 113 reception module; 114 reception control circuit; 115, 116, 117, 118 coupling capacitor; 120, 122, 123, 124, 131, 132, 133, 135, 220, 222, 223, 224, 231, 232, 233, 235 control circuit; 121, 130, 221, 230 transmission circuit; 125, 134, 225, 234 reception circuit; 141, 142, 143, 144 series resistor; 151, 153 input electrode; 152, 154 output electrode; 161, 162 output-stage transistor; 200 host board; 200A circuit board; 201 connector; 202 host processing circuit; 203, 204, 205, 206 pin; 207 terminal; 241, 242 pull-up resistor; 251, 252 input terminal; 300 PON system; 303 PON line; 304 optical splitter; 305 main-line optical fiber; 306 branch-line optical fiber; A1, A2 direction

1. A pluggable optical module comprising:
a circuit board insertable to and removable from a connector of a host board;
a plurality of first electrodes arranged in a first direction on a first surface of the circuit board, the first direction crossing an insert direction in which the pluggable optical module is to be inserted; and
a plurality of second electrodes arranged in the first direction on the first surface of the circuit board, the second electrodes being arranged on a host board side associated with the host board, with respect to the plurality of first electrodes, wherein
the plurality of first electrodes and the plurality of second electrodes are arranged in accordance with a layout rule for tolerating electrical impact occurring when at least one of a plurality of terminals of the connector that are configured to be brought into contact with respective first electrodes of the plurality of first electrodes contacts any electrode of the plurality of second electrodes.

2. The pluggable optical module according to claim 1, wherein
the plurality of first electrodes are assigned with signals to be transmitted at a first transmission speed, and
the plurality of second electrodes are assigned with signals to be transmitted at a second transmission speed different from the first transmission speed.

3. The pluggable optical module according to claim 1, wherein
the plurality of second electrodes include an input electrode assigned with a control signal to be input from the host board to the pluggable optical module, and
the pluggable optical module further comprises:
a control circuit that receives the control signal; and
a series resistor connected in series between the input electrode and the control circuit.

4. The pluggable optical module according to claim 1, wherein
the plurality of second electrodes include an output electrode assigned with a control signal to be output from the pluggable optical module to the host board, and
the pluggable optical module further comprises:
a control circuit that outputs the control signal; and
an output stage transistor including a collector or a drain connected to the output electrode, and
the output stage transistor forms an open collector circuit or an open drain circuit.

5. A host board comprising:
a connector attachable to and detachable from a host interface of a pluggable optical module, the host interface of the pluggable optical module having a surface on which a plurality of first electrodes are arranged in a row and a plurality of second electrodes are arranged in a row, the plurality of second electrodes being arranged on a host board side associated with the host board, with respect to the plurality of first electrodes; and
a circuit board on which the connector is mounted,
the connector including:
a plurality of first terminals to be brought into contact with respective first electrodes of the plurality of first electrodes of the host interface; and
a plurality of second terminals to be brought into contact with respective second electrodes of the plurality of second electrodes of the host interface, wherein
the plurality of first terminals and the plurality of second terminals are arranged on the connector in accordance with a pin assignment for tolerating electrical impact that may occur when at least one of the plurality of first terminals of the connector contacts any electrode of the plurality of second electrodes of the host interface.

6. The host board according to claim 5, wherein
the plurality of first terminals are assigned with signals to be transmitted at a first transmission speed, and
the plurality of second terminals are assigned with signals to be transmitted at a second transmission speed different from the first transmission speed.

7. The host board according to claim 5, wherein
the plurality of second terminals include an input terminal assigned with a control signal to be input from the pluggable optical module to the host board, and
the host board further comprises:
a control circuit that receives the control signal; and
a pull-up resistor connected between the input terminal and a positive voltage.
